(19) United States
(12) Patent Application Publication
(10) Pub. No.: US 2024/0339433 A1
(43) Pub. Date: Oct. 10, 2024

(54) SEMICONDUCTOR DEVICE WITH A THROUGH DIELECTRIC VIA

(71) Applicant: Micron Technology, Inc., Boise, ID (US)

(72) Inventors: Bharat Bhushan, Taichung (TW); Nevil N. Gajera, Meridian, ID (US); Akshay N. Singh, Boise, ID (US); Kunal R. Parekh, Boise, ID (US)

(21) Appl. No.: 18/610,268

(22) Filed: Mar. 20, 2024

Related U.S. Application Data
(60) Provisional application No. 63/458,405, filed on Apr. 10, 2023.

(51) Int. Cl. H01L 25/065; H01L 23/00; H01L 23/31; H01L 23/48; H01L 25/00; H10B 80/00

(52) U.S. Cl. CPC H01L 25/0652; H01L 23/31; H01L 23/481; H01L 24/08; H01L 24/19; H01L 24/20; H01L 24/80; H01L 24/94; H01L 25/50; H10B 80/00; H01L 2224/08145; H01L 2224/19; H01L 2224/21; H01L 2224/80895; H01L 2224/80896; H01L 2224/94; H01L 2225/06548

(57) ABSTRACT

A semiconductor device with a through dielectric via is disclosed. The semiconductor device assembly can include a semiconductor die and multiple stacks of semiconductor dies coupled with the semiconductor die at different lateral locations. Dielectric material can be disposed at the semiconductor die between the multiple stacks of semiconductor dies. The through dielectric via can extend entirely through the dielectric material to the semiconductor die such that the through dielectric via couples with circuitry at the semiconductor die. In this way, the through dielectric via can provide power to the semiconductor die (e.g., exclusive of the multiple stacks of semiconductor dies).

### CROSS-REFERENCE TO RELATED APPLICATION(S)

The present application claims priority to U.S. Provisional Patent Application No. 63/458,405, filed Apr. 10, 2023, the disclosure of which is incorporated herein by reference in its entirety.

### TECHNICAL FIELD

The present disclosure generally relates to semiconductor device assemblies and more particularly relates to a semiconductor device with a through dielectric via.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly in accordance with an embodiment of the present technology.

FIGS. 2-7 illustrate simplified schematic cross-sectional views of a series of steps for fabricating semiconductor device assemblies in accordance with embodiments of the present technology.

FIG. 8 illustrates a schematic view of a system that includes a semiconductor device assembly configured in accordance with an embodiment of the present technology.

FIG. 9 illustrates a method of fabricating a semiconductor device assembly in accordance with an embodiment of the present technology.

### DETAILED DESCRIPTION

Multiple semiconductor dies can be packaged into a single semiconductor device to enable the multiple semiconductor dies to operate cooperatively as a single device. The performance requirements for semiconductor devices continue to increase while the spatial constraints for these devices decrease. Accordingly, semiconductor devices are designed with increased density, which can introduce additional challenges. For example, high-density semiconductor devices can be at risk of overheating due to an increased amount of heat generated by the dense circuitry in device. Thus, semiconductor devices can benefit from thermal regulation.

One such technique to address this challenge and others includes implementing a through dielectric via within a semiconductor device. For example, a semiconductor device can include a semiconductor die (e.g., a logic die) and multiple stacks of semiconductor dies (e.g., memory dies) coupled with the semiconductor die at different lateral locations. The semiconductor die can be implemented at the top of the semiconductor device to enable the semiconductor die to dissipate heat more effectively. Moreover, the semiconductor die at the top of the semiconductor device can replace a cap (e.g., undeveloped silicon), thereby limiting the cost and complexity of the semiconductor device. Dielectric material can be disposed at the semiconductor die between the multiple stacks of semiconductor dies. A through dielectric via can extend entirely through the dielectric material to the semiconductor die such that the through dielectric via couples with circuitry at the semiconductor die. In this way, the through dielectric via can provide power to the semiconductor die (e.g., exclusive of the multiple stacks of semiconductor dies) even though the semiconductor die is located at the top of the semiconductor device.

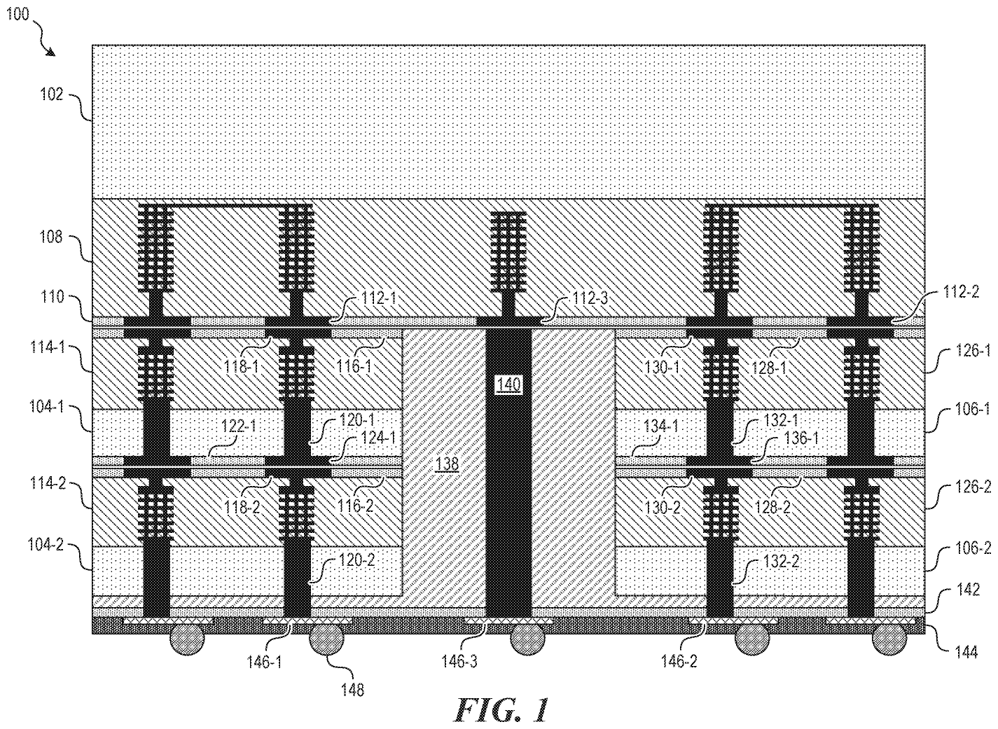

FIG. 1 illustrates a semiconductor device assembly 100 that includes a semiconductor die 102 (e.g., a logic die) coupled (e.g., electrically and mechanically) with a first stack of semiconductor dies 104 (e.g., semiconductor die 104-1 and semiconductor die 104-2) and a second stack of semiconductor dies 106 (e.g., semiconductor die 104-1 and semiconductor die 104-2). The semiconductor die 102 can be singulated from a wafer of semiconductor dies (e.g., logic dies) after the first stack of semiconductor dies 104 and the second stack of semiconductor dies 106 are assembled onto the wafer of semiconductor dies. The first stack of semiconductor dies 104 or the second stack of semiconductor dies 106 can similarly be singulated from a stack of semiconductor wafers.

The semiconductor die 102 includes a metallization layer 108 having traces, lines, vias, transistors, diodes, and other circuitry at an active side of the semiconductor die 102. A dielectric material 110 (e.g., silicon oxide, silicon nitride, silicon carbide, or silicon carbon nitride) can be disposed over the front side of the semiconductor die 102. The semiconductor die 102 can include contact pads 112 (e.g., contact pads 112-1, contact pads 112-2, and contact pad 112-3) disposed at the dielectric material 110 and electrically coupled with the circuitry at the semiconductor die 102.

The stack of semiconductor dies 104 can include metallization layers 114 (e.g., metallization layer 114-1 and metallization layer 114-2) at the active sides of the semiconductor dies 104. Dielectric material 116 (e.g., dielectric material 116-1 and dielectric material 116-2) can be disposed over the active sides of the semiconductor dies 104. The semiconductor dies 104 can include contact pads 118 (e.g., contact pads 118-1 and contact pads 118-2) disposed at the dielectric material 116 and electrically coupled with the circuitry at the semiconductor dies 104. Through silicon vias (TSVs) 120 (e.g., TSVs 120-1 and TSVs 120-2) can extend from the metallization layers 114 to the inactive sides of the semiconductor dies 104. Dielectric material 122 (e.g., dielectric material 122-1) can be disposed over the inactive side of the semiconductor dies 104. The TSVs 120 can be exposed through the dielectric material 122, and contact pads 124 (e.g., contact pads 124-1) can be disposed at and electrically coupled with the TSVs 120.

The semiconductor dies 104 couple (e.g., hybrid bond) with one another (e.g., in a front-to-back arrangement) to form a stack. As illustrated, the dielectric material 122-1 directly bonds with the dielectric material 116-2, and the contact pads 124-1 and the contact pads 118-2 couple to form interconnects (e.g., metal-metal interconnects) electrically coupling the semiconductor die 104-1 and the semiconductor die 104-2. Moreover, the stack of semiconductor dies 104 couple (e.g., hybrid bond) with the semiconductor die 102 at a first lateral location. In aspects, the semiconductor die 104-1 can bond with the semiconductor die 102 in a front-to-front arrangement. As illustrated, the dielectric material 116-1 directly bonds with the dielectric material 110, and the contact pads 118-1 couple with the contact pads 112-1 to form interconnects (e.g., metal-metal interconnects) electrically coupling the semiconductor die 104-1 with the semiconductor die 102.

The semiconductor dies 106 can similarly include metallization layers 126 (e.g., metallization layer 126-1 and metallization layer 126-2), dielectric material 128 (e.g., dielectric material 128-1 and dielectric material 128-2) disposed over the metallization layers 126, and contact pads 130 (e.g., contact pads 130-1 and contact pads 130-2) disposed at the dielectric material 128 and electrically coupled with the metallization layers 126. Moreover, the semiconductor dies 106 can include TSVs 132 (e.g., TSVs 132-1 and TSVs 132-2) extending from the metallization layers 126 to the inactive sides of the semiconductor dies 106. Dielectric material 134 (e.g., dielectric material 134-1) can be disposed at the inactive sides of the semiconductor dies 106. The TSVs 132 can be exposed through the dielectric material 134, and contact pads 136 (e.g., contact pads 136-1) can be disposed on the TSVs 132.

The semiconductor dies 106 similarly couple (e.g., hybrid bond) with one another (e.g., in a front-to-back arrangement) to form a stack. As illustrated, the dielectric material 134-1 directly bonds with the dielectric material 128-2, and the contact pads 136-1 and the contact pads 130-2 couple to form interconnects (e.g., metal-metal interconnects) electrically coupling the semiconductor die 106-1 and the semiconductor die 106-2. Moreover, the stack of semiconductor dies 106 can similarly couple (e.g., hybrid bond) with the semiconductor die 102 at a second lateral location. In aspects, the semiconductor die 104-1 can bond with the semiconductor die 102 in a front-to-front arrangement. As illustrated, the dielectric material 128-1 directly bonds with the dielectric material 110, and the contact pads 130-1 couple with the contact pads 112-2 to form interconnects (e.g., metal-metal interconnects) electrically coupling the semiconductor die 106-1 with the semiconductor die 102.

Dielectric material 138 (e.g., dielectric fill) can be disposed outside of the footprint of the stack of semiconductor dies 104 and the footprint of the stack of semiconductor dies 106. The dielectric material 138 can include, for example, silicon oxide, silicon nitride, silicon carbide, or silicon carbon nitride. In aspects, the dielectric material 138 can be disposed between the stack of semiconductor dies 104 and the stack of semiconductor dies 106. For instance, the dielectric material 138 can be disposed at the semiconductor die 102 exposed beyond the footprint of the stack of semiconductor dies 104 and the stack of semiconductor dies 104. As illustrated, the dielectric material 138 can extend over a surface of the stack of semiconductor dies 104 or the stack of semiconductor dies 106 that is distal from the semiconductor die 102.

A through dielectric via 140 can extend entirely through the dielectric material 138 to the semiconductor die 102. For example, the through dielectric via 140 can extend from a surface of the dielectric material 138 distal from the semiconductor die 102 to the semiconductor die 102. The through dielectric via 140 can electrically couple (e.g., hybrid bond) with the contact pad 112-3 at the semiconductor die 102 to provide power to the semiconductor die 102 through the contact pad 112-3. For example, a first end of the through dielectric via 140 distal from the semiconductor die 102 can couple with a power source, and a second end of the through dielectric via 140 can couple with the contact pad 112-3 such that the through dielectric via 140 can provide power from the power source to the first semiconductor die 102. In some cases, the contact pad 112-3 can be a buried contact (e.g., at the metallization layer 108) that is not exposed through the dielectric material 110. Thus, the through dielectric via 140 can extend at least partially through the semiconductor die 102 to the buried contact such that the through dielectric via 140 electrically couples with the buried contact. The through dielectric via 140 can be larger or have a larger aspect ratio (e.g., 10, 15, 20, 25, and so on) than TSVs between semiconductor dies (e.g., TSVs 120 and TSVs 132). For example, the through dielectric via 140 can have a width of two microns and a height of 30 microns, and the TSVs 120 and TSVs 132 can have a width of one micron and a height of five microns.

A dielectric material 142 can be disposed over the dielectric material 138, the stack of semiconductor dies 104, and the stack of semiconductor dies 106. The TSVs 120-2, the TSVs 132-2, and the through dielectric via 140 can be exposed through the dielectric material 142 to enable electrical contact therewith. For example, a redistribution layer 144 can be disposed over the dielectric material 138, the stack of semiconductor dies 104, and the stack of semiconductor dies 106 (e.g., at the dielectric material 142). The redistribution layer 144 can include contact pads 146 (e.g., contact pads 146-1, contact pads 146-2, and contact pad 146-3) and connective circuitry (e.g., traces, lines, vias, and other connective structures) disposed throughout layers of dielectric material. The contact pads 146 can be disposed at the exposed circuitry connected with the semiconductor die 102, the stack of semiconductor dies 104, and the stack of semiconductor dies 106. For example, the contact pads 146-1 can electrically couple with the TSVs 120-2, the contact pads 146-2 can electrically couple with the TSVs 132-2, and the contact pad 146-3 can electrically couple with the through dielectric via 140. The redistribution layer 144 can include connective circuitry (not shown) that connects the contact pads 146 to contact pads (not shown) exposed at a surface distal from the semiconductor die 102. The contact pads can connect to additional circuit components (e.g., a substrate or additional semiconductor die) through connective structures (e.g., solder bumps 148) to provide functionality (e.g., power, ground, or input/output (I/O) signaling) to the semiconductor device assembly 100.

Although not illustrated, the semiconductor device assembly 100 can include additional through dielectric vias extending at least partially through the dielectric material 138. For example, an additional through dielectric via can extend entirely through the dielectric material 138 between the redistribution layer 144 and the semiconductor die 102. The additional through dielectric via can couple with an additional contact pad at the semiconductor die 102 to provide power, ground, or I/O signaling to the semiconductor die 102. In yet other aspects, the semiconductor device assembly 100 can include a dummy through dielectric via that extends at least partially through the dielectric material 138. The dummy through dielectric via can be electrically isolated from circuitry at the semiconductor device assembly (e.g., in the semiconductor die 102, the semiconductor dies 104, and the semiconductor dies 106). Thus, the dummy through dielectric via does not communicate signaling to the semiconductor die 102, the semiconductor dies 104, or the semiconductor dies 104. Instead, the dummy through dielectric via can be used to dissipate heat away from the semiconductor device assembly. In aspects, circuitry (e.g., traces, lines, vias, transistors, diodes, and other electrical components) is not implemented between multiple through dielectric vias. For example, dielectric material 138 between the through dielectric vias is not a suitable material on which to dispose circuitry.

Although the stack of semiconductor dies 104 and the stack of semiconductor dies 106 are illustrated as two semiconductor dies, other implementations are possible that include more or fewer semiconductor dies. Similarly, other implementations exist that include the stack of semiconductor dies 104 or the stack of semiconductor dies 106 arranged differently. For example, stack of semiconductor dies 104 or the stack of semiconductor dies 106 could be replaced with a stack of semiconductor dies assembled in a back-to-front arrangement, (e.g., instead of a front-to-back arrangement). Similarly, the stack of semiconductor dies 104 or the stack of semiconductor dies 106 can couple with the semiconductor die 102 in a back-to-back arrangement, a front-to-back arrangement, or a back-to-front arrangement (e.g., instead of a front-to-front arrangement). In yet other aspects, the stack of semiconductor dies 104 or the stack of semiconductor dies 106 can be replaced with a single semiconductor die or a stack of semiconductor dies having 3, 4, 5, 6, 8, 10, 12, 14, 16, or any other number of semiconductor dies.

Although illustrated in cross section with two stacks of semiconductor dies, stack of semiconductor dies 104 and stack of semiconductor dies 106, electrically coupled with the semiconductor die 102, the semiconductor device assembly 100 can include any number of stacks of semiconductor dies. For example, the semiconductor device assembly 100 can include 3, 4, 5, 6, 8, 10, 12, 14, 16, or any other number of stacks of semiconductor dies electrically coupled with the semiconductor die 102. The stacks of semiconductor dies can be electrically coupled with the semiconductor die 102 in any number of arrangement. For example, the stacks of semiconductor dies can be coupled with the semiconductor die 102 in a rectangle pattern.

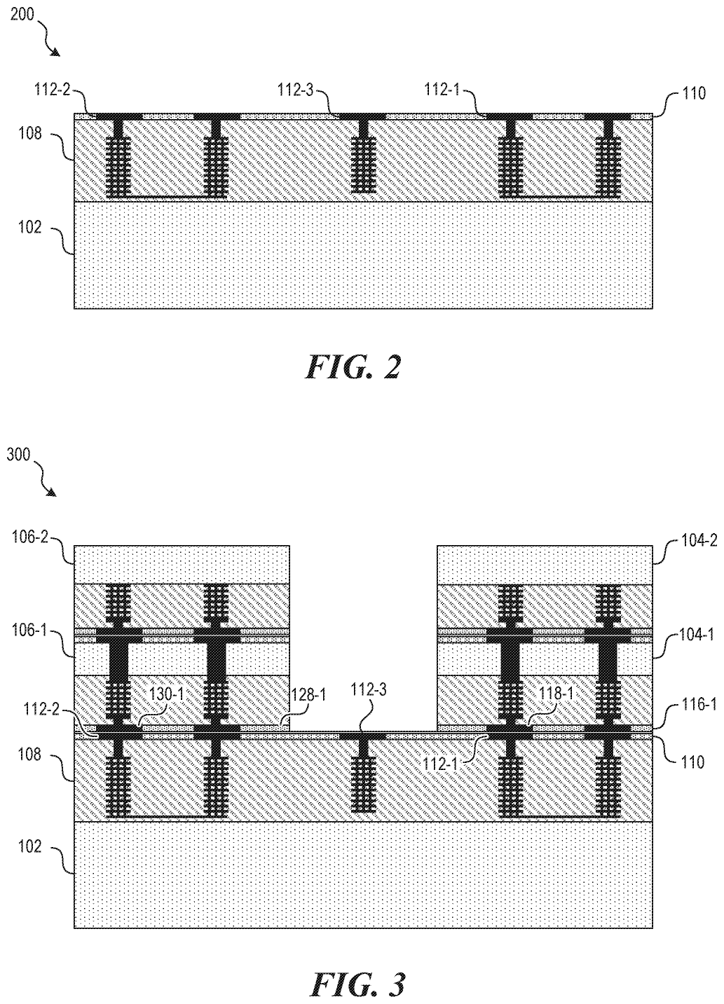

This disclosure now turns to a series of steps for fabricating semiconductor device assemblies in accordance with embodiments of the present technology. Specifically, FIGS. 2-7 illustrate simplified schematic cross-sectional views of a series of steps for fabricating semiconductor device assemblies in accordance with an embodiment of the present technology. The steps are illustrated with respect to a specific embodiment for ease of description. However, the steps described with respect to FIGS. 2-7 could be performed to fabricate semiconductor device assemblies in accordance with other embodiments.

Beginning with FIG. 2 at stage 200, a simplified schematic cross-sectional view of the semiconductor die 102 (e.g., a logic die) is illustrated. The semiconductor die 102 can include a metallization layer 108 at which circuitry is disposed. A layer of dielectric material 110 can be disposed over the metallization layer 108. Contact pads 112 can be disposed at the dielectric material 110 and electrically coupled with the circuitry at the metallization layer 108 to enable interconnects between the semiconductor die 102 and additional dies to be formed.

Although illustrated as a singulated semiconductor die 102, the steps described with respect to FIGS. 2-7 can be performed at the wafer level. For example, the semiconductor die 102 can be a single semiconductor die on a wafer of semiconductor dies. Accordingly, the steps described with respect to FIGS. 2-7 can be performed at the die level to fabricate a single semiconductor device or at the wafer level to fabricate a plurality of semiconductor devices.

FIG. 3 illustrates a simplified schematic cross-sectional view of stage 300, where a stack of semiconductor dies 104 and the stack of semiconductor dies 106 are coupled with the semiconductor die 102 at a first lateral location and a second lateral location, respectively. The stack of semiconductor dies 104 and the stack of semiconductor dies 106 can be singulated from a stack of wafers and coupled with the semiconductor die 102 (e.g., stack-to-wafer hybrid bond). Alternatively, each individual semiconductor die of the stack of semiconductor dies 104 and the stack of semiconductor dies 106 can be individually stacked. The stack of semiconductor dies 104 and the stack of semiconductor dies 106 can be coupled with the semiconductor die 102 through the dielectric material 110 and the contact pads 112. For example, the dielectric material 116-1 can directly bond with the dielectric material 110, and the contact pads 118-1 and the contact pads 112-1 can couple to form interconnects electrically coupling the semiconductor die 102 and the stack of semiconductor dies 104. Similarly, the dielectric material 128-1 can directly bond with the dielectric material 110, and the contact pads 130-1 and the contact pads 112-2 can couple to form interconnects electrically coupling the semiconductor die 102 and the stack of semiconductor dies 106.

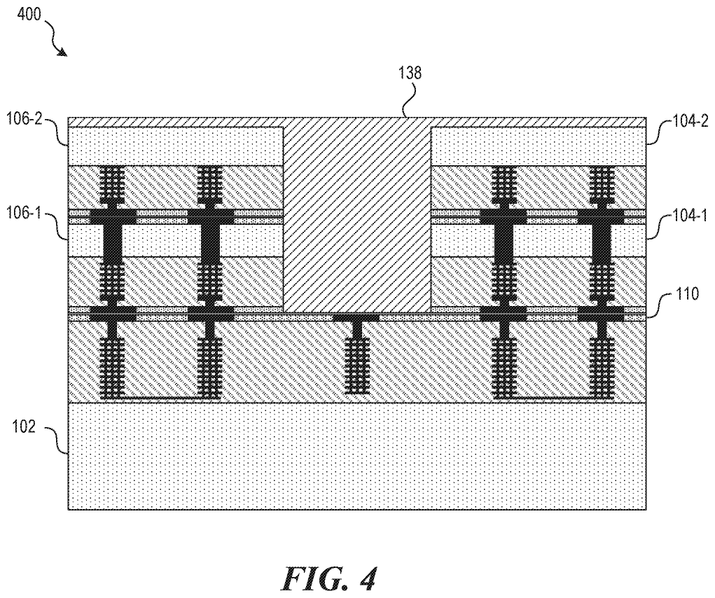

FIG. 4 illustrates a simplified schematic cross-sectional view of stage 400, where a dielectric material 138 is disposed at the semiconductor die 102 between the stack of semiconductor dies 104 and the stack of semiconductor dies 106. In aspects, the dielectric material 138 (e.g., dielectric fill) can be disposed at the semiconductor die 102 exposed beyond the footprint of the stack of semiconductor dies 104 and the footprint of the stack of semiconductor dies 106. In aspects, the dielectric material 138 can mechanically support and protect the semiconductor device assembly. In other aspects, the dielectric material 138 can improve the thermal regulation of the semiconductor device assembly. The dielectric material 138 can include any dielectric material, for instance, silicon oxide, silicon nitride, silicon carbide, or silicon carbon nitride. The dielectric material 138 can similarly be disposed through any appropriate technique, for example, dispensing, chemical vapor deposition, or physical vapor deposition.

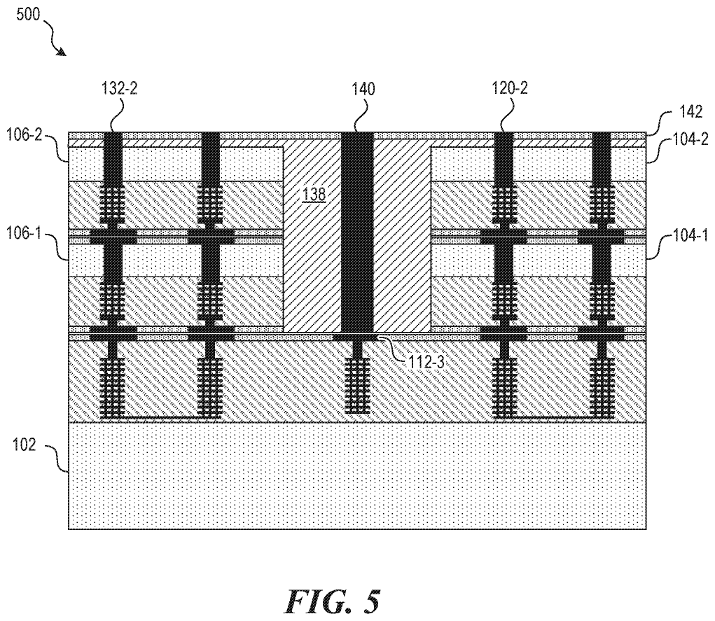

As illustrated, the dielectric material 138 can be disposed over a distal end of the stack of semiconductor dies 104 and the stack of semiconductor dies 106 opposite the semiconductor die 102. The dielectric material 138 can be planarized (e.g., using chemical-mechanical planarization (CMP) or grinding) to create a planar surface distal from the semiconductor die 102. In some cases, the planarization can expose (e.g., and thin) the stack of semiconductor dies 104 and the stack of semiconductor dies 106 (e.g., at the semiconductor die 104-2 or the semiconductor die 106-2). In this way, electrical contact can be made with the stack of semiconductor dies 104 and the stack of semiconductor dies 106 without requiring circuitry extending through the dielectric material 138. In other cases, the planarization does not expose the stack of semiconductor dies 104 and the stack of semiconductor dies 106, and a portion of the dielectric material 138 remains over a distal end of the stack of semiconductor dies 104 and the stack of semiconductor dies 106. As a result, vias can be disposed through the dielectric material 138 to make electrical contact with the semiconductor die 104-2, the semiconductor die 106-2, or even the semiconductor die 102, as illustrated in FIG. 5.

FIG. 5 illustrates a simplified schematic cross-sectional view of a stage 500, where vias are disposed through the dielectric material 138. For example, a layer of dielectric material 142 (e.g., a dielectric block) can be disposed over the stack of semiconductor dies 104, the stack of semiconductor dies 106, and the dielectric material 138 to protect and insulate the circuitry thereat. TSVs 120-2 can be implemented through the dielectric material 138 and the substrate of the semiconductor die 104-2 such that the TSVs 120-2 contact circuitry at the semiconductor die 104-2 and are exposed through the dielectric material 138. For example, via holes can be created (e.g., drilled or etched) through the dielectric material 138 and the substrate of the semiconductor die 104-2, and conductive material can be deposited in the via holes to implement the TSVs 120-2. The TSVs 120-2 can be exposed through the layer of dielectric material 142. In this way, electrical contact can be made with the stack of semiconductor dies 104 through the TSVs 120-2. TSVs 132-2 can similarly be implemented at the semiconductor die 106-2 to enable electrical contact with the stack of semiconductor dies 106.

Moreover, a through dielectric via 140 can be implemented through the dielectric material 138 to the contact pad 112-3 at the semiconductor die 102. For example, a via hole can be created entirely through the dielectric material 138 to the contact pad 112-3. The via hole for the through dielectric via 140 can created through a process different from the via hole for the TSVs 120 or the TSVs 132. For example, the via holes for the TSVs 120 or the TSVs 132 can be created using a dry etch through the semiconductor material with a Bosch process. In contrast, the via hole for the through dielectric via 140 can be dry etched through the dielectric material 138 without a Bosch process. Conductive material can be deposited in the via hole to implement the through dielectric via 140. The through dielectric via 140 can thus electrically couple with the semiconductor die 102 through the contact pad 112-3 and be exposed through the dielectric material 138 (e.g., and the dielectric material 142) at a distal end opposite the semiconductor die. In contrast to the TSVs 120 or the TSVs 132, the through dielectric via 140 need not be surrounded by a dielectric liner disposed in the via hole, for example, because the through dielectric via 140 extends through dielectric material 138 and not semiconductive material. Thus, the through dielectric via 140 may not have the same stress, isolation, or diffusion concerns as a TSV disposed through a semiconductor material. In aspects, the through dielectric via 140 can be utilized to deliver power or other signals (e.g., ground or I/O signals) to circuitry at the semiconductor die 102.

Although FIGS. 3-5 have been illustrated and described with respect to specific embodiments, other such embodiments are possible. For example, although the stack of semiconductor dies 104 and the stack of semiconductor dies 106 are described as being mounted to the semiconductor die 102 as stacks, the stack of semiconductor dies 104 and the stack of semiconductor dies 106 can instead be mounted to the semiconductor die 102 through wafer-wafer bonding. Specifically, the stack of semiconductor dies 104, the stack of semiconductor dies 106, and the dielectric material 138 can collectively form a reconstructed wafer that is bonded to the semiconductor die 102.

In some cases, the reconstructed wafer could be formed by adhering the stack of semiconductor dies 104 and the stack of semiconductor dies 106 to a carrier wafer and disposing the dielectric material 138 between the stack of semiconductor dies 104 and the stack of semiconductor dies 106 (e.g., at a portion of the carrier wafer exposed beyond the stack of semiconductor dies 104 and the stack of semiconductor dies 106). In aspects, adhering the stack of semiconductor dies 104 and the stack of semiconductor dies 106 to the carrier wafer as singulated die stacks enables the semiconductor the stack of semiconductor dies 104 and the stack of semiconductor dies 106 to be tested and selected as “known good cubes,” which can improve yield.

In other cases, the stack of semiconductor dies 104 and the stack of semiconductor dies 106 can be adhered to the carrier wafer as a wafer stack. The wafer stack can be sawed between the stack of semiconductor dies 104 and the stack of semiconductor dies 106 to remove the portion of the wafer stack between the die stacks while leaving the stack of semiconductor dies 104 and the stack of semiconductor dies 106 adhered to the carrier. The dielectric material 138 can then be disposed between the stack of semiconductor dies 104 and the stack of semiconductor dies 106 (e.g., at a portion of the carrier wafer exposed by the stack of semiconductor dies 104 and the stack of semiconductor dies 106).

Once the dielectric material 138 is disposed, the stack of semiconductor dies 104, the stack of semiconductor dies 106, and the dielectric material 138 can collectively form a reconstructed wafer that is bonded to the semiconductor die 102. Wafer-level processes can be performed on the reconstructed wafer. For example, the reconstructed wafer can be bonded to the semiconductor die 102 (e.g., a wafer that includes the semiconductor die 102) through wafer-level processes, which can have improved qualities over stack- or die-level processes. For instance, wafer-level processes can create semiconductor devices with higher yield or having interconnects that are better aligned.

Given that wafer-level processing can be performed on the reconstructed wafer, in some cases, the through dielectric via 140 can be created through the dielectric material 138 (e.g., to the carrier wafer) before the reconstructed wafer is bonded to the semiconductor die 102. For example, a via hole can be created entirely through the dielectric material 138 on the reconstructed wafer, and conductive material can be disposed in the via hole to implement the through dielectric via. In this way, the through dielectric via 140 can be exposed at a coupling surface of the reconstructed wafer such that the through dielectric via 140 can be electrically coupled (e.g., hybrid bonded) with the contact pad 112-3 when the restructured wafer is bonded with the semiconductor die 102. Alternatively, the through dielectric via 140 can be created after the reconstructed wafer is coupled with the semiconductor die 102.

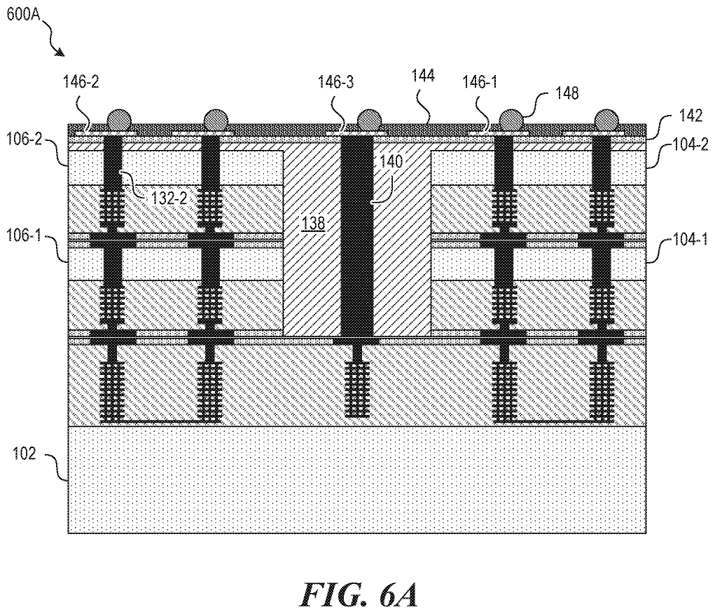

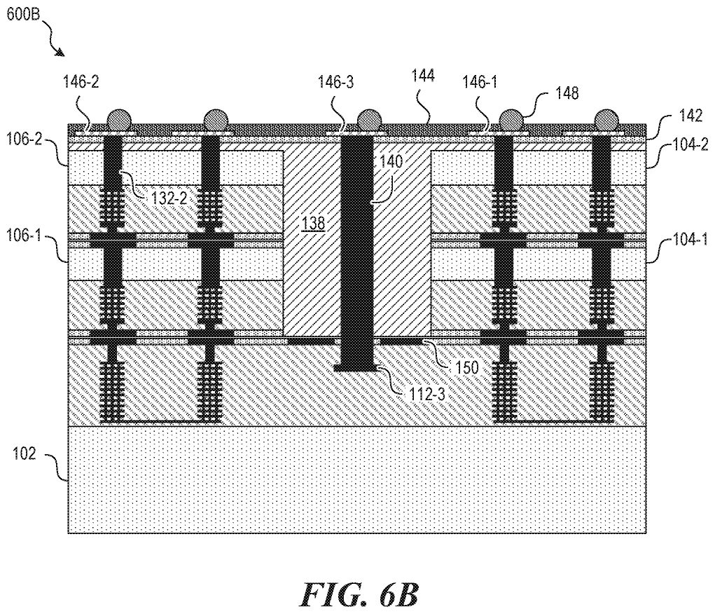

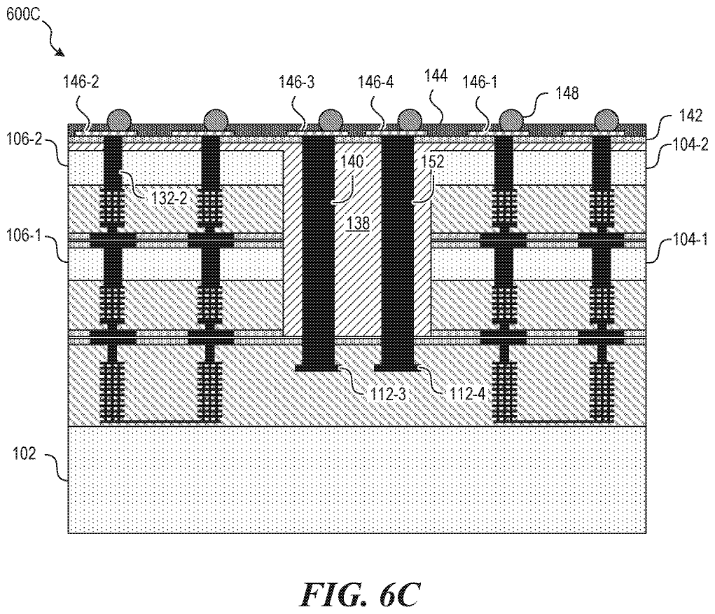

Although illustrated in cross section such that only two semiconductor die stacks are shown, additional die stacks can be stacked on the wafer of semiconductor dies 206. For example, the semiconductor device assembly can include 4, 8, 12, 30, 50, 100, or any other number of semiconductor die stacks. Similarly, although only two iterations of die stacking are illustrated, additional layers of semiconductor dies can be stacked onto the semiconductor device assembly by repeating the operations described with respect to FIGS. 5 and 6. Accordingly, the total number of semiconductor dies in each stack of semiconductor dies coupled to the wafer of semiconductor dies 206 can equal 2, 3, 4, 5, 6, 8, 10, 12, 14, 16, or any other number of semiconductor dies.

Turning next to FIG. 6A, a simplified schematic cross-sectional view of a semiconductor device assembly at a stage 600A is illustrated. At stage 600A, a redistribution layer 144 is formed at distal end opposite the semiconductor die 102. The redistribution layer 144 may be formed from layers of conductive material (e.g., copper, gold, or silver) and insulating material (e.g., dielectric material, polymer, or photo-sensitive dielectric material). The conductive material and the insulating material may be disposed on the coupling surface through any appropriate method. In aspects, the redistribution layer 144 may be formed through sputtering, plating, photolithography, etching, spin coating, or any other appropriate technique.

Conductive material may be used to create contact pads 146-1 corresponding to the exposed portion of the TSVs 120-2, contact pads 146-2 corresponding to the exposed portion of the TSVs 132-2, and contact pad 146-3 corresponding to the exposed portion of the through dielectric via 140. Insulating material may be disposed to separate the conductive material and implement separate components. For example, layers of conductive material may be disposed to implement routing layers having internal circuitry that connects to the contact pads 146. Dielectric layers may be disposed between the routing layers to separate these layers. Contacts (illustrated in combination with the contact pads 146 for simplicity) may similarly be disposed at a surface of the redistribution layer 144 distal from the semiconductor die 102 (e.g., in a ball grid array (BGA)). The contacts can electrically couple with one or more external circuit components (e.g., a substrate and additional semiconductor die) through solder bumps 148, or other connective structures, to provide functionality (e.g., power, ground, I/O signaling) to the stack of semiconductor dies 104, the stack of semiconductor dies 106, and the semiconductor die 102 through the TSVs 120-2, the TSVs 132-2, and the through dielectric via 140.

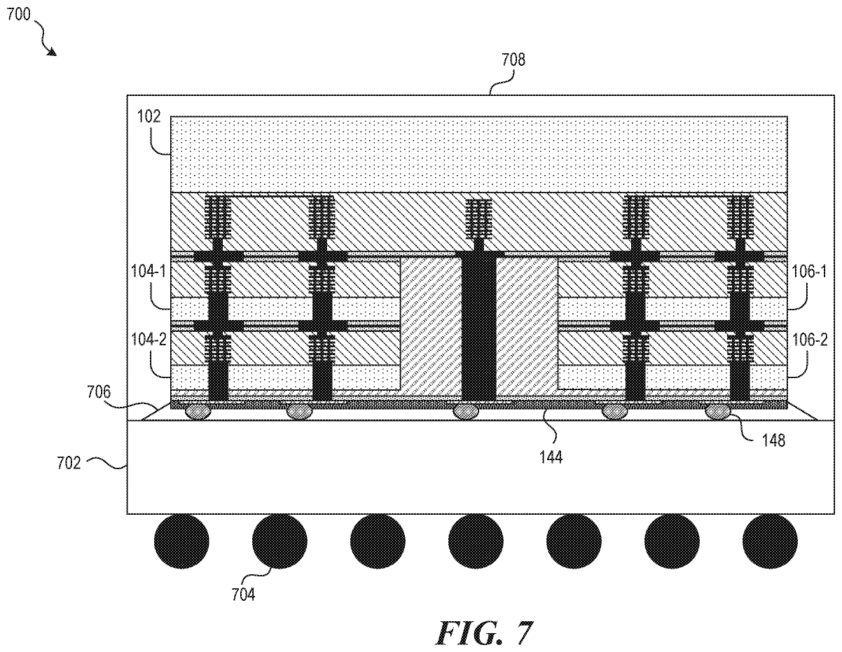

As discussed above, semiconductor device assembly can be fabricated at the wafer level such that multiple semiconductor devices are fabricated on a single wafer. For instance, the semiconductor die 102 can be a single semiconductor die on a wafer of semiconductor dies. Accordingly, the wafer of semiconductor dies that includes the semiconductor die 102 can be sawed between adjacent dies to singulate the semiconductor device assembly into a plurality of semiconductor device assemblies (e.g., including the illustrated assembly implemented on the semiconductor die 102). Although not illustrated, the dielectric material 138 can be disposed between different semiconductor dies on the wafer of semiconductor dies that includes the semiconductor die 102. Thus, singulating the wafer of semiconductor dies can include sawing through the dielectric material 138 between the different semiconductor dies. As a result, the singulated semiconductor device assembly illustrated can include a dielectric sidewall that at least partially surrounds the stack of semiconductor dies 104 or the stack of semiconductor dies 106. Once singulated, the semiconductor device assembly can be assembled onto a substrate, as illustrated in FIG. 7.

FIG. 6B illustrates another embodiment of a semiconductor device assembly at a stage 600B. In contrast to FIG. 6A, the contact pad 112-3 illustrated in FIG. 6B is a buried contact pad embedded in the semiconductor die 102 (e.g., a back-end-of-line contact pad). As a result, the through dielectric via 140 can extend at least partially through the semiconductor die 102 to the contact pad 112-3 such that electrical contact can be made with the contact pad 112-3. The semiconductor die 102 can include dummy pads 150 that improve the planarity of the semiconductor die 102 or the bonding of the semiconductor die 102 with the dielectric material 138.

FIG. 6C illustrates another embodiment of a semiconductor device assembly at a stage 600C, where one or more additional through dielectric vias can be disposed through the dielectric material 138. For example, an additional through dielectric via 152 can be disposed through the dielectric material 138 to an additional contact pad 112-4 (e.g., a buried contact pad or a surface contact pad) at the semiconductor die 102. The additional through dielectric via 152 can provide additional signals to the semiconductor die 102, for example, power, ground, or I/O signals. In some cases, the additional through dielectric via 152 can provide a direct signal path (e.g., exclusive of the stack of semiconductor dies 104 or the stack of semiconductor dies 106) from the redistribution layer 144 to the semiconductor die 102. In this way, other components on a package-level substrate (not shown) attached to the redistribution layer 144 through the solder bumps 148 can communicate with the semiconductor die 102 through the additional through dielectric via 152. In yet other aspects, a dummy through dielectric via can be created that at least partially extends through the dielectric material 138. The dummy through dielectric via can be electrically isolated from circuitry at the semiconductor die 102 and thus incapable of carrying signals to or from the semiconductor die 102. Instead, the dummy through dielectric via can be used to dissipate heat from the semiconductor device assembly or improve the bonding between various device components (e.g., the stack of semiconductor dies 104 and the semiconductor die 102).

FIG. 7 illustrates a simplified schematic cross-sectional view of a semiconductor device assembly at stage 700, where the singulated semiconductor device illustrated in FIG. 6A is assembled onto a package-level substrate 702 (e.g., printed-circuit board (PCB), interposer, etc.) and packaged. For example, redistribution layer 144 of the singulated semiconductor device is coupled with the package-level substrate 702 through the solder bumps 148 such that the semiconductor die 102 is located above the stack of semiconductor dies 104 and the stack of semiconductor dies 106. The package-level substrate 702 can include routing circuitry that connects the contacts (not shown) at the upper surface at which the solder bumps 148 are coupled to contacts (not shown) at the lower surface at which connective structures 704 are disposed. The package-level substrate 702 can couple with external circuit components (e.g., a motherboard) through the connective structures 704 to provide functionality (e.g., power, ground, I/O signaling) to the device assembly.

An underfill material 706 (e.g., capillary underfill) can be provided between the singulated semiconductor device and the package-level substrate 702 to provide electrical insulation to the connective structures (e.g., solder bumps 148) and structurally support the assembly. The semiconductor device assembly can further include an encapsulant material 708 (e.g., a mold resin compound) that at least partially encapsulates the semiconductor die 102, the stack of semiconductor dies 104, the stack of semiconductor dies 106, and the package-level substrate 702 to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, a vertical stack of semiconductor dies or a single semiconductor die, mutatis mutandis.

In accordance with one aspect of the present disclosure, the semiconductor devices illustrated in the assemblies of FIGS. 1-7 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby). In some embodiments, the semiconductor device assemblies can communicate using a tightly coupled memory (TCM) protocol).

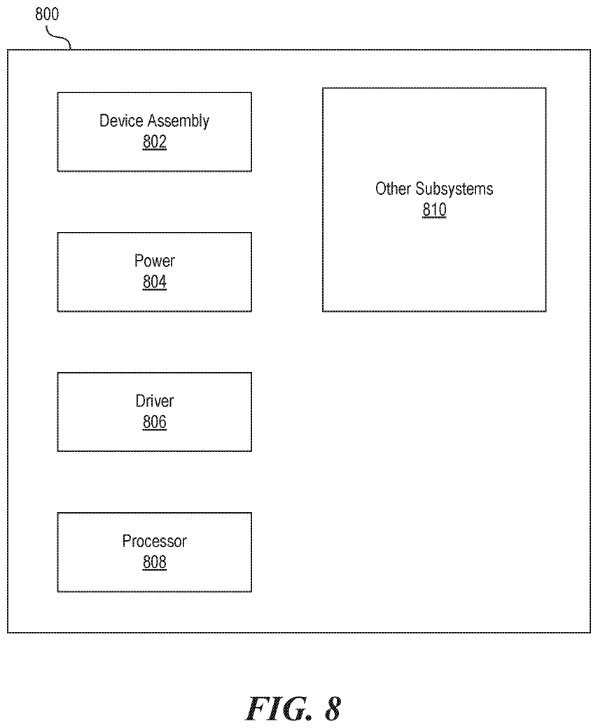

Any one of the semiconductor devices and semiconductor device assemblies described above with reference to FIGS. 1-7 can be incorporated into any of a myriad of larger and/or more complex systems, a representative example of which is system 800 shown schematically in FIG. 8. The system 800 can include a semiconductor device assembly 802 (e.g., a discrete semiconductor device), a power source 804, a driver 806, a processor 808, and/or other subsystems or components 810. The semiconductor device assembly 802 can include features generally similar to those of the semiconductor device assemblies described above with reference to FIGS. 1-7. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances and other products. Components of the system 800 may be housed in a single unit or distributed over multiple, interconnected units (e.g., through a communications network). The components of the system 800 can also include remote devices and any of a wide variety of computer-readable media.

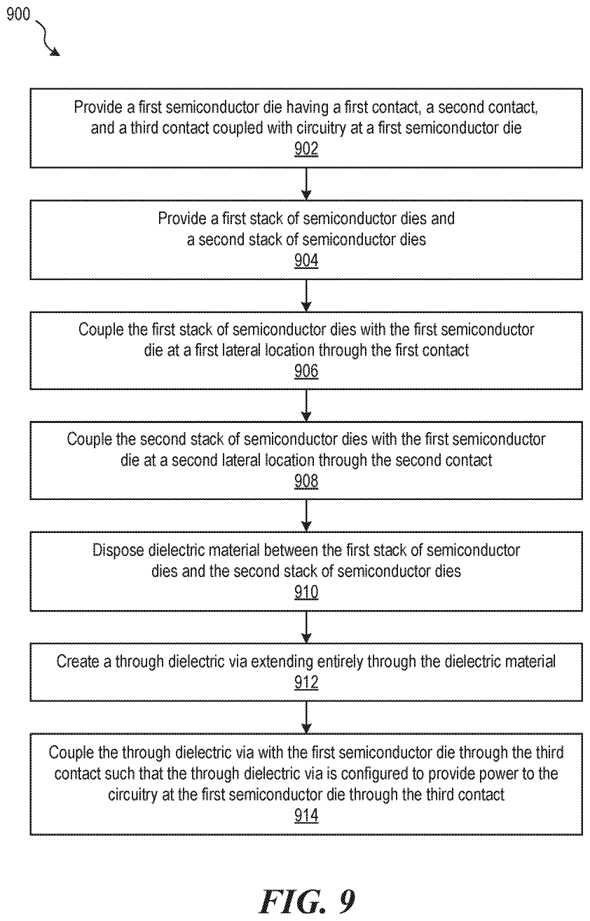

FIG. 9 illustrates an example method 900 for fabricating a semiconductor device assembly in accordance with an embodiment of the present technology. Although illustrated in a particular configuration, one or more operations of the method 900 may be omitted, repeated, or reorganized. Additionally, the method 900 may include other operations not illustrated in FIG. 9, for example, operations detailed in one or more other methods described herein.

At 902, a first semiconductor die is provided. The first semiconductor die has a first contact, a second contact, and a third contact coupled with circuitry at the first semiconductor die. At 904, a first stack of semiconductor dies and a second stack of memory dies are provided. At 906, the first stack of semiconductor dies is coupled with the first semiconductor die at a first lateral location through the first contact. At 908, the second stack of semiconductor dies is coupled with the first semiconductor die at a second lateral location through the second contact. At 910, a dielectric material is disposed between the first stack of semiconductor dies and the second stack of semiconductor dies. At 912, a through dielectric via extending entirely through the dielectric material is created. At 914, the through dielectric via is coupled with the first semiconductor die through the third contact such that the through dielectric via is configured to provide power to the circuitry at the first semiconductor die through the third contact. In doing so, a semiconductor device with a through dielectric via can be implemented.

Specific details of several embodiments of semiconductor devices and associated systems and methods are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or 3DI applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor die having a first contact, a second contact, and a third contact coupled with circuitry at the first semiconductor die;
a first stack of semiconductor dies coupled, through the first contact, with the first semiconductor die at a first lateral location, the first stack of semiconductor dies including a second semiconductor die distal from the first semiconductor die and having a fourth contact coupled with circuitry at the second semiconductor die, the fourth contact exposed at a first distal end of the first stack of semiconductor dies opposite the first semiconductor die;
a second stack of semiconductor dies coupled, through the second contact, with the first semiconductor die at a second lateral location, the second stack of semiconductor dies including a third semiconductor die distal from the first semiconductor die and having a fifth contact coupled with circuitry at the third semiconductor die, the fifth contact exposed at a second distal end of the second stack of semiconductor dies opposite the first semiconductor die;
a dielectric material disposed at a portion of the first semiconductor die that is exposed beyond a first footprint of the first stack of semiconductor dies and beyond a second footprint of the second stack of semiconductor dies; and
a through dielectric via extending entirely through the dielectric material to the third contact and configured to provide power to the circuitry at the first semiconductor die.

2. The semiconductor device assembly of claim 1, wherein:
the fourth contact includes a through silicon via extending through the second semiconductor die; and
the fifth contact includes an additional through silicon via extending through the third semiconductor die.

3. The semiconductor device assembly of claim 1, wherein:
the third contact comprises a buried contact; and
the through dielectric via extends at least partially through the first semiconductor die to the buried contact.

4. The semiconductor device assembly of claim 1, further comprising:
a sixth contact coupled with the circuitry at the first semiconductor die; and
an additional through dielectric via extending entirely through the dielectric material to the sixth contact, the additional through dielectric via configured to communicate signaling to or from the circuitry at the first semiconductor die.

5. The semiconductor device assembly of claim 1, further comprising a dummy through dielectric via extending at least partially through the dielectric material, the dummy through dielectric via electrically isolated from the circuitry at the first semiconductor die.

6. The semiconductor device assembly of claim 1, further comprising a redistribution layer disposed over the first stack of semiconductor dies, the second stack of semiconductor dies, and the dielectric material, the redistribution layer coupled with the fourth contact, the fifth contact, and the through dielectric via.

7. The semiconductor device assembly of claim 1, wherein:
the dielectric material is disposed over the first distal end of the first stack of semiconductor dies and the second distal end of the second stack of semiconductor dies; and
the fourth contact and the fifth contact are exposed through the dielectric material.

8. The semiconductor device assembly of claim 1, wherein:
the first semiconductor die comprises a logic die; and
the first stack of semiconductor dies and the second stack of semiconductor dies comprise memory dies.

9. A method for fabricating a semiconductor device assembly, comprising:
providing a first semiconductor die having a first contact, a second contact, and a third contact coupled with circuitry at the first semiconductor die;
providing a first stack of semiconductor dies and a second stack of memory dies;
coupling, through the first contact, the first stack of semiconductor dies with the first semiconductor die at a first lateral location;
coupling, through the second contact, the second stack of semiconductor dies with the first semiconductor die at a second lateral location;
disposing dielectric material between the first stack of semiconductor dies and the second stack of semiconductor dies;
creating a through dielectric via extending entirely through the dielectric material; and
coupling the through dielectric via with the first semiconductor die through the third contact such that the through dielectric via is configured to provide power to the circuitry at the first semiconductor die through the third contact.

10. The method of claim 9, further comprising:
coupling a plurality of wafers of semiconductor dies to create a stack of semiconductor wafers; and
singulating the first stack of semiconductor dies from the stack of semiconductor wafers.

11. The method of claim 9, further comprising, after coupling the first stack of semiconductor dies and the second stack of semiconductor dies with the first semiconductor die, disposing the dielectric material at the first semiconductor die between the first stack of semiconductor dies and the second stack of semiconductor dies.

12. The method of claim 9, further comprising:
adhering the first stack of semiconductor dies to a carrier wafer;
adhering the second stack of semiconductor dies to the carrier wafer;
disposing the dielectric material at the carrier wafer between the first stack of semiconductor dies and the second stack of semiconductor dies to form a reconstructed wafer that includes the first stack of semiconductor dies, the second stack of semiconductor dies, and the dielectric material; and
coupling the reconstructed wafer to the first semiconductor dies such that the first stack of semiconductor dies couples, through the first contact, with the first semiconductor die at the first lateral location and the second stack of semiconductor dies couples, through the second contact, with the first semiconductor die at the second lateral location.

13. The method of claim 12, further comprising:
coupling a plurality of wafers of semiconductor dies to create a stack of semiconductor wafers that include the first stack of semiconductor dies and the second stack of semiconductor dies, the stack of semiconductor wafers adhered to the carrier wafer; and
removing a portion of the stack of semiconductor wafers between the first stack of semiconductor dies and the second stack of semiconductor dies.

14. The method of claim 12, further comprising:
prior to coupling the reconstructed wafer to the first semiconductor die, creating the through dielectric via extending entirely through the dielectric material; and
coupling the reconstructed wafer to the first semiconductor dies such that the through dielectric via couples with the first semiconductor die through the third contact.

15. The method of claim 9, wherein the third contact is a buried contact, the method further comprising:
creating a via hole extending entirely through the dielectric material and at least partially through the first semiconductor die to the buried contact; and
disposing conductive material in the via hole to implement the through dielectric via coupled with the buried contact.

16. The method of claim 9, further comprising:
disposing the dielectric material over the first stack of semiconductor dies and the second stack of semiconductor dies;
creating a second via extending at least partially through the dielectric material to circuitry at a second semiconductor die of the first stack of semiconductor dies; and
creating a third via extending through the dielectric material to circuitry at a third semiconductor die of the second stack of semiconductor dies.

17. The method of claim 9, further comprising disposing a redistribution layer over the first stack of semiconductor dies, the second stack of semiconductor dies, and the dielectric material, the redistribution layer coupled with the first stack of semiconductor dies, the second stack of semiconductor dies, and the through dielectric via.

18. The method of claim 9, wherein the first semiconductor die includes a fourth contact coupled with the circuitry at the first semiconductor die, the method further comprising:
creating an additional through dielectric via extending entirely through the dielectric material; and
coupling the additional through dielectric via with the first semiconductor die through the fourth contact such that the additional through dielectric via is configured to provide communication signaling to or from the circuitry at the first semiconductor die through the fourth contact.

19. The method of claim 9, further comprising creating a dummy through dielectric via extending at least partially through the dielectric material, the dummy via electrically isolated from the circuitry at the first semiconductor die.

20. A semiconductor device assembly, comprising:
a redistribution layer;
a first stack of semiconductor dies coupled with the redistribution layer at a first lateral location;
a second stack of semiconductor dies coupled with the redistribution layer at a second lateral location;
a first semiconductor die having a larger footprint than the first stack of semiconductor dies and the second stack of semiconductor dies combined, the first semiconductor die coupled with the first stack of semiconductor dies and the second stack of semiconductor dies at a distal end opposite the redistribution layer;
a dielectric material disposed between the redistribution layer, the first stack of semiconductor dies, the second stack of semiconductor dies, and the first semiconductor die; and
a through dielectric via extending through the dielectric material between the redistribution layer and the first semiconductor die, the through dielectric via configured to provide power from the redistribution layer to the first semiconductor die.
